(19) United States
(12) Patent Application Publication
(10) Pub. No.: US 2025/0387850 A1
(43) Pub. Date: Dec. 25, 2025

(54) OPTICAL PROCESSING APPARATUS, OPTICAL SYSTEM, AND LASER PROCESSING METHOD

(71) Applicant: DISCO CORPORATION, Tokyo (JP)

(72) Inventors: Keiji Nomaru, Tokyo (JP); Nobuyuki Kimura, Japan (JP)

(21) Appl. No.: 19/225,194

(22) Filed: Jun. 2, 2025

(30) Foreign Application Priority Data
Jun. 25, 2024 (JP) 2024-101696

(51) Int. Cl. B23K 26/035; H01L 21/67

(52) U.S. Cl. CPC B23K 26/035; H01L 21/67092

(57) ABSTRACT

An optical processing apparatus for irradiating a workpiece with a laser beam is provided. The optical processing apparatus includes a laser oscillator configured to emit the laser beam, an irradiating unit configured to irradiate the workpiece with the laser beam emitted from the laser oscillator, an irradiating unit moving mechanism configured to move the irradiating unit, a plurality of optical elements arranged on an optical path of the laser beam emitted from the laser oscillator to guide the laser beam from the laser oscillator to the irradiating unit, and an adjustment moving mechanism configured to move the optical element with respect to a movement direction of the irradiating unit. Along with a movement of the irradiating unit, the adjustment moving mechanism moves the optical element in an opposite direction to the movement direction of the irradiating unit, thereby adjusting an optical path length of the laser beam.

### BACKGROUND OF THE INVENTION

### Field of the Invention

The present invention relates to an optical processing apparatus that irradiates a workpiece such as a semiconductor wafer with a laser beam and an optical system that guides light emitted from a light source to an irradiation target.

### Description of the Related Art

Device chips such as integrated circuits (ICs) are essential parts in electronic apparatuses such as mobile phones or personal computers. In a device chip manufacturing process, a plurality of streets (planned dividing lines) are set in a lattice manner on a surface of a wafer, a device is formed in each of a plurality of regions that are demarcated by the streets, and thereafter, the wafer is divided along the streets. Individually divided device chips are thus obtained.

A cutting apparatus that cuts a wafer by an annular cutting blade, for example, is used to divide the wafer. Besides, recently, the implementation of a technology for dividing a wafer by laser processing has also been under way. A laser beam emitted from an oscillator is guided to a wafer as a workpiece by various kinds of optical elements (mirrors, a condensing lens, and the like), and the wafer is thus subjected to processing such as groove formation or cutting.

For example, technologies related to such laser processing are described in PCT Patent Publication WO2017/175839 (hereinafter, referred to as Patent Document 1), Japanese Patent Laid-Open No. 2010-99667 (hereinafter, referred to as Patent Document 2), and the like.

Proposed in Patent Document 1 is an optical processing apparatus having a mechanism that moves a nozzle head while irradiating a processing region with light such as a laser beam from the nozzle head and scans the processing region.

Here, at a time of performing the laser processing, it is important from a viewpoint of stability of the processing that a laser beam be applied with its spot diameter and irradiation position held as constant as possible in a workpiece to be irradiated with the laser beam. Meanwhile, in an apparatus including a laser beam irradiating unit (nozzle head) which changes in position, as in the optical processing apparatus described in Patent Document 1, the distance of a path of the laser beam (optical path length) from a light source to the irradiation target sometimes changes when the laser beam irradiating unit moves.

A variation in the optical path length can lead to a variation in a state of irradiation of the irradiation target (an enlargement of the spot diameter, a variation in the position of a focus, or the like) in a case where the laser beam is not precisely collimated light, a case where there are optical elements that converge and diffuse the laser beam in the middle of an optical path, a case where the laser beam is branched in the middle of the optical path, or other cases.

Therefore, according to a technology described in Patent Document 2, in an optical system including a movable optical part on an optical path from a light emitting unit to a light receiving unit, a mirror is further provided in the middle of the optical path and is moved according to a movement of the movable optical part, thereby holding the optical path length constant.

That is, according to the technology described in Patent Document 2, when an objective lens as a movable optical part is moved to the right (in a direction in which the optical path length becomes small) in the optical system illustrated in FIG. 1 of Patent Document 2, for example, the mirror is correspondingly moved to the right (in a direction away from the light source) to lengthen the optical path length in front of and behind the mirror. A variation in the optical path length is thus canceled out. Conversely, when the objective lens is moved to the left (in a direction in which the optical path length becomes large), the mirror is operated in such a manner as to correspondingly move to the left (in a direction of approaching the light source) to shorten the optical path length in front of and behind the mirror.

### SUMMARY OF THE INVENTION

However, in such a system as described in Patent Document 2, a direction in which the movable optical part is moved and a direction in which the mirror is correspondingly moved to suppress a variation in the optical path length are the same, which cause a great variation in the gravity center of the processing apparatus.

It is accordingly an object of the present invention to provide a processing apparatus, an optical system, and a laser processing method that can suitably adjust an optical path length according to a movement of a movable optical part while suppressing a variation in a gravity center.

In accordance with an aspect of the present invention, there is provided an optical processing apparatus for irradiating a workpiece with a laser beam, the optical processing apparatus including a laser oscillator configured to emit the laser beam, an irradiating unit configured to irradiate the workpiece with the laser beam emitted from the laser oscillator, an irradiating unit moving mechanism configured to move the irradiating unit, a plurality of optical elements arranged on an optical path of the laser beam emitted from the laser oscillator to guide the laser beam from the laser oscillator to the irradiating unit, and an adjustment moving mechanism configured to move the optical element with respect to a movement direction of the irradiating unit. Along with a movement of the irradiating unit, the adjustment moving mechanism moves the optical element in an opposite direction to the movement direction of the irradiating unit, thereby adjusting an optical path length of the laser beam.

In the aspect of the present invention, preferably, the plurality of optical elements are arranged on the optical path of the laser beam such that reversed portions are formed at two positions or more on the optical path of the laser beam with respect to the movement direction of the irradiating unit, and among the optical elements, the optical element forming an even-numbered reversed portion of the optical path of the laser beam as viewed from the irradiating unit is movable by the adjustment moving mechanism.

In accordance with another aspect of the present invention, there is provided an optical system for guiding light to an irradiation target region by a plurality of optical elements on an optical path, the optical system including a movable optical part on the optical path configured to change the optical path by being moved and an adjustment moving mechanism configured to move the optical element with respect to a movement direction of the movable optical part. Along with a movement of the movable optical part, the adjustment moving mechanism moves the optical element in an opposite direction to the movement direction of the movable optical part, thereby adjusting an optical path length of a laser beam.

In the other aspect of the present invention, preferably, the plurality of optical elements are arranged such that reversed portions are formed at two positions or more on the optical path with respect to the movement direction of the movable optical part, and among the optical elements, the optical element forming an even-numbered reversed portion of the optical path as viewed from the movable optical part is movable by the adjustment moving mechanism.

In the other aspect of the present invention, a direction of incidence of the light on the movable optical part along the optical path may be parallel with the movement direction of the movable optical part. As the plurality of optical elements, at least first to fourth reflection type optical elements may be provided on an upstream side of the movable optical part. The light may enter the first reflection type optical element in the same direction as the direction of incidence of the light on the movable optical part with respect to the movement direction of the movable optical part. The light may be reflected by the first reflection type optical element in a direction intersecting the movement direction of the movable optical part and may enter the second reflection type optical element. The light may be reflected by the second reflection type optical element in an opposite direction to the direction of incidence of the light on the movable optical part and may enter the third reflection type optical element with respect to the movement direction of the movable optical part. The light may be reflected by the third reflection type optical element in the direction intersecting the movement direction of the movable optical part and may enter the fourth reflection type optical element.

In accordance with a further aspect of the present invention, there is provided a laser processing method using the optical system described above, the laser processing method including adjusting an optical path length of a laser beam by, along with a movement of the movable optical part, moving the optical element by the adjustment moving mechanism in an opposite direction to the movement direction of the movable optical part, and irradiating a workpiece with the laser beam.

According to the optical processing apparatus, the optical system, and the laser processing method in accordance with the respective aspects of the present invention, in adjusting the optical path length by moving the optical element along with the movement of the movable optical part (irradiating unit), the direction of the movement of the optical element can be made opposite to the direction of the movement of the movable optical part. It is thus possible to suitably adjust the optical path length while suppressing a variation in the gravity center.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a perspective view illustrating an example (first embodiment) of a form of an optical processing apparatus;

FIG. 2 is a perspective view illustrating an example of a form of a workpiece;

FIG. 3 is a conceptual diagram schematically illustrating an arrangement of an optical system in the optical processing apparatus according to the first embodiment;

FIG. 4 is a conceptual diagram schematically illustrating another example (second embodiment) of the arrangement of the optical system in the optical processing apparatus;

FIG. 5 is a conceptual diagram schematically illustrating yet another example (third embodiment) of the arrangement of the optical system in the optical processing apparatus;

FIG. 6 is a conceptual diagram schematically illustrating yet another example (fourth embodiment) of the arrangement of the optical system in the optical processing apparatus;

FIG. 7 is a perspective view illustrating another example (fifth embodiment) of the form of the optical processing apparatus;

FIG. 8 is a conceptual diagram schematically illustrating an arrangement of an optical system in the optical processing apparatus according to the fifth embodiment, and illustrates the arrangement as viewed from a Y-direction;

FIG. 9 is a conceptual diagram schematically illustrating the arrangement of the optical system in the optical processing apparatus according to the fifth embodiment, and illustrates the arrangement as viewed from an X-direction; and

FIG. 10 is a flowchart of assistance in explaining a procedure of a laser processing method.

### DETAILED DESCRIPTION OF THE PREFERRED EMBODIMENTS

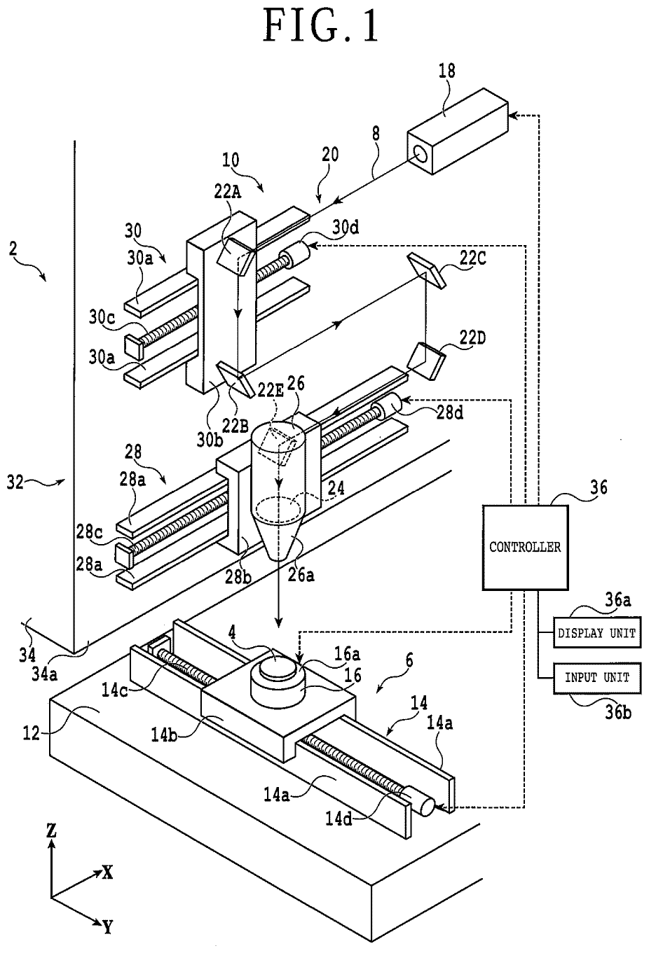

Embodiments of the present invention will hereinafter be described in detail with reference to the accompanying drawings. FIG. 1 is a perspective view schematically illustrating a configuration of an optical processing apparatus according to a first embodiment of the present invention. Here, a laser processing apparatus 2 is illustrated as the optical processing apparatus. It is to be noted that the optical processing apparatus is not limited to the laser processing apparatus, and as the optical processing apparatus, any of various apparatuses can be assumed which include an optical system that guides light emitted from a light source to an irradiation target by various kinds of optical elements (mirrors, a condensing lens, and the like).

In FIG. 1, an X-direction, a Y-direction, and a Z-direction denote the orientations of three axes orthogonal to one another in a three-dimensional space. The X-direction (left-right direction) and the Y-direction (front-rear direction) are horizontal directions orthogonal to each other. The Z-direction (upward-downward direction) is a direction orthogonal to the X-direction and the Y-direction, and is a vertical direction. In addition, in the laser processing apparatus 2 according to the first embodiment, a direction along the X-direction is set as a processing feed direction, and a direction along the Y-direction is set as an indexing feed direction.

Incidentally, while expressions such as “along the X-direction” and “along an XY plane” are used in the present specification, these expressions do not necessarily mean that the orientations of members and surfaces exactly coincide with or are parallel with these axes and planes. For example, these expressions also indicate that two members or surfaces are oriented in substantially the same direction while forming a slightly oblique angle with each other, and that the angle or movement of a member includes a component in the relevant direction.

The laser processing apparatus 2 includes a workpiece holding mechanism 6 that supports and moves a workpiece 4, and an irradiating mechanism 10 including an optical system that irradiates the workpiece 4 with a laser beam 8.

The workpiece holding mechanism 6 includes a Y-axis moving mechanism 14 provided on an upper surface of a base 12 and a chuck table 16 as a holding unit attached to the Y-axis moving mechanism 14.

The base 12 is a pedestal forming a base portion of the workpiece holding mechanism 6. The upper surface of the base 12 is a flat surface along a horizontal plane (XY plane). The Y-axis moving mechanism 14 is provided on this flat surface.

The Y-axis moving mechanism 14 includes a pair of Y-axis guide rails 14a that extend in parallel with each other along the Y-direction on the upper surface of the base 12. A Y-axis moving table 14b that has a surface along the horizontal plane (XY plane) is fitted to upper portions of the pair of Y-axis guide rails 14a so as to be slidable along the longitudinal direction of the Y-axis guide rails 14a.

A Y-axis ball screw 14c is disposed between the pair of Y-axis guide rails 14a along the longitudinal direction of the Y-axis guide rails 14a. A nut (not illustrated) is provided to the back side (lower side) of the Y-axis moving table 14b. The Y-axis ball screw 14c penetrates the nut.

A Y-axis pulse motor 14d for rotating the Y-axis ball screw 14c is coupled to one end in the longitudinal direction of the Y-axis ball screw 14c. When the Y-axis pulse motor 14d is driven, the Y-axis ball screw 14c rotates about its axis, and the Y-axis moving table 14b moves on the Y-axis guide rails 14a along the Y-direction.

The chuck table 16 as a holding unit for holding the workpiece 4 is attached to an upper surface of the Y-axis moving table 14b. An upper surface of the chuck table 16 is a flat surface along the horizontal plane (XY plane). The upper surface of the chuck table 16 is connected to a suction source (not illustrated) such as an ejector via a valve (not illustrated) or the like through a flow passage (not illustrated) which is formed within the chuck table 16. When the suction source is actuated, a negative pressure is produced on the upper surface of the chuck table 16. Such an object as the workpiece 4 held on the upper surface can be sucked thereon. That is, the upper surface of the chuck table 16 constitutes a holding surface 16a that holds the workpiece 4.

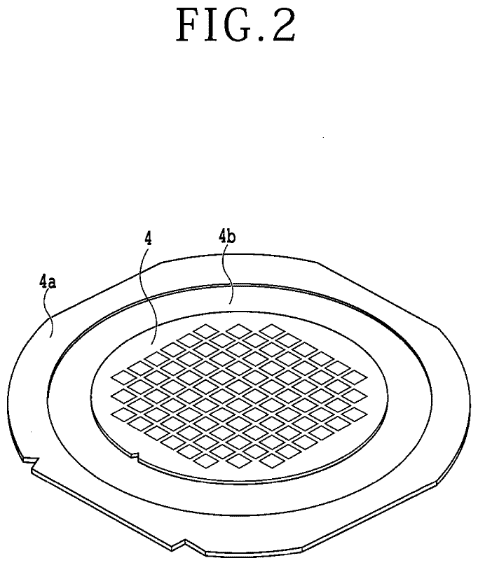

FIG. 2 is a perspective view illustrating an example of a form of the workpiece 4. The workpiece 4 is, for example, a disk-shaped wafer formed of a semiconductor material such as single crystal silicon. The workpiece 4 has a plurality of streets (planned dividing lines) set thereon in a lattice manner and is demarcated by the streets into a plurality of rectangular regions. A device such as an integrated circuit (IC), a large scale integrated circuit (LSI), a light emitting diode (LED), or a microelectromechanical systems (MEMS) device is formed on a surface of each of the regions demarcated by the streets.

However, there is no limitation on the kind, material, shape, structure, size, and the like of the workpiece 4. For example, the workpiece 4 may be a substrate (wafer) formed of a material such as a semiconductor (GaAs, InP, GaN, SiC, or the like), sapphire, glass, ceramics, resin, or metal. In addition, there is also no limitation on the kind, number, shape, structure, size, arrangement, and the like of the devices formed on the workpiece 4. The workpiece 4 may not have devices formed thereon.

When the workpiece 4 is handled by such an apparatus as the laser processing apparatus 2 illustrated in FIG. 1, for the purpose of facilitating the handling, e.g., transportation and holding, of the workpiece 4, the workpiece 4 is held by a frame 4a as illustrated in FIG. 2, and they are handled as a frame unit. The frame 4a is a plate-shaped part formed of metal such as stainless steel (SUS), for example. An opening that penetrates the frame 4a in a thickness direction is provided in a central portion of the frame 4a. The diameter of the opening is set larger than the diameter of the workpiece 4.

The workpiece 4 is supported by the frame 4a via an adhesive sheet 4b. The adhesive sheet 4b is, for example, constituted by a circular film-shaped base material having a larger diameter than the central opening of the frame 4a and an adhesive layer provided on the base material. The base material includes, for example, resin such as polyolefin, polyvinyl chloride, or polyethylene terephthalate. The adhesive layer is formed of a material such as an epoxy-based, acryl-based, or rubber-based adhesive, for example. This material is applied to at least one surface of the base material to form the adhesive layer. An ultraviolet curable resin can also be used as the material of the adhesive layer.

In a state in which the workpiece 4 is disposed inside the opening of the frame 4a, a central portion of the adhesive sheet 4b is affixed to the workpiece 4, and a peripheral portion of the adhesive sheet 4b is affixed to the frame 4a. The workpiece 4 is thus supported by the frame 4a.

As illustrated in FIG. 1, the irradiating mechanism 10 includes a laser oscillator 18 as light source equipment and an optical system 20 that guides the laser beam 8 emitted as collimated light from the laser oscillator 18 to a region where the workpiece 4 is placed (irradiation target region).

The laser oscillator 18 is, for example, a piece of equipment that generates and emits a laser beam by laser oscillation, such as a YAG laser, a YVO4 laser, or a YLF laser. The emitted laser beam 8 is guided to the irradiation target region, where the workpiece 4 is placed, by the optical system 20 and is applied to the workpiece 4. The optical system 20 includes a plurality of optical elements provided on an optical path of the laser beam 8. The traveling direction, shape, condensing position, and the like of the laser beam 8 are controlled by these optical elements.

A configuration of the optical system 20 will be described. The optical system 20 according to the first embodiment includes, as optical elements, a plurality of mirrors 22A, 22B, 22C, 22D, and 22E that reflect the laser beam 8 emitted from the laser oscillator 18, and a condensing lens 24 that condenses the laser beam 8 reflected by the mirrors 22A to 22E and irradiates the workpiece 4 with the laser beam 8.

The mirrors 22A to 22E are reflection type optical elements. Dielectric multilayer film mirrors or the like, for example, can be used as the mirrors 22A to 22E. A convex lens or the like, for example, can be used as the condensing lens 24. The laser beam 8 emitted from the laser oscillator 18 is reflected by the mirrors 22A, 22B, 22C, and 22D in this order and is guided to an irradiating unit 26.

The irradiating unit 26 includes the mirror 22E and the condensing lens 24. The laser beam 8 that has entered the inside of the irradiating unit 26 is reflected by the mirror 22E and enters the condensing lens 24. The laser beam 8 that has entered the condensing lens 24 is refracted by the condensing lens 24 and condensed at a target position (for example, on a surface or in an internal portion of the workpiece 4).

However, there is no limitation on the kinds of the optical elements constituting the optical system 20, and appropriate optical elements can be used as long as the optical elements can appropriately guide the laser beam 8 to the irradiation target region. For example, the optical system 20 may be provided with an optical element such as a mirror or a lens other than those cited above or an optical element such as a polarizing beam splitter (PBS), a diffractive optical element (DOE), or a liquid crystal on silicon-spatial light modulator (LCOS-SLM).

In the first embodiment, among the above-described optical elements constituting the optical system 20, the condensing lens 24 and the mirror 22E located right before the condensing lens 24 (on an upstream side of the optical path of the laser beam 8) configure part of the irradiating unit 26 that irradiates the workpiece 4 with the laser beam 8. In addition, the irradiating unit 26 is configured to be movable along the X-direction. A direction of the movement of the irradiating unit 26 and a direction of incidence of the laser beam 8 on the irradiating unit 26 from the mirror 22D are parallel with each other.

In the following, such a part as the irradiating unit 26 that is a constituent element of the optical system 20 movably provided on the optical path and is moved to change the optical path will be referred to as a movable optical part as required. In addition, a mechanism that moves the irradiating unit 26 as the movable optical part will be referred to as an irradiating unit moving mechanism 28.

In the first embodiment, in addition to this, the mirrors 22A and 22B located on the most upstream side of the optical path of the laser beam 8 among the optical elements are also configured to be movable in the X-direction in order to adjust the length of the optical path. A mechanism for moving the optical elements in order to adjust the optical path length as described above will be referred to as an adjustment moving mechanism 30.

The parts constituting the optical system 20 (the mirrors 22A to 22E, the condensing lens 24, and the irradiating unit 26) are supported by a supporting mechanism 32. The supporting mechanism 32 illustrated in FIG. 1 includes a supporting frame 34 having a supporting surface 34a along an XZ plane, and the mirrors 22A to 22E, the condensing lens 24, and the irradiating unit 26 are arranged along the XZ plane on the supporting surface 34a.

The irradiating unit moving mechanism 28 includes a pair of X-axis guide rails 28a that extend in parallel with each other along the X-direction on the supporting surface 34a of the supporting frame 34. An X-axis moving table 28b that has a surface along a vertical plane (XZ plane) perpendicular to the Y-direction is fitted to the pair of X-axis guide rails 28a so as to be slidable along the longitudinal direction of the X-axis guide rails 28a. An X-axis ball screw 28c is disposed between the pair of X-axis guide rails 28a along the longitudinal direction of the X-axis guide rails 28a. A nut (not illustrated) is provided on the back side (facing the supporting surface 34a of the supporting frame 34) of the X-axis moving table 28b. The X-axis ball screw 28c penetrates the nut.

An X-axis pulse motor 28d for rotating the X-axis ball screw 28c is coupled to one end in the longitudinal direction of the X-axis ball screw 28c. When the X-axis pulse motor 28d is driven, the X-axis ball screw 28c rotates about its axis, and the X-axis moving table 28b moves along the longitudinal direction of the X-axis guide rails 28a (in a direction along the X-direction).

The irradiating unit 26 is attached to the X-axis moving table 28b. The irradiating unit 26 includes the mirror 22E and the condensing lens 24, and a lower portion of the irradiating unit 26 is configured as an irradiation head 26a that emits the laser beam 8.

In the optical system 20 according to the first embodiment, as illustrated in FIG. 1, the laser beam 8 enters the mirror 22E within the irradiating unit 26 along the X-direction and is reflected downward (in a direction along the Z-direction) by the mirror 22E. The condensing lens 24 is disposed below the mirror 22E. The laser beam 8 reflected downward by the mirror 22E passes through the condensing lens 24 and is refracted thereby. Then, the laser beam 8 further passes through the irradiation head 26a and is applied to the workpiece 4 placed below the irradiation head 26a.

The adjustment moving mechanism 30 may have the following mechanism which is substantially similar to that of the irradiating unit moving mechanism 28, for example.

The adjustment moving mechanism 30 includes a pair of X-axis guide rails 30a that extend in parallel with each other along the X-direction on the supporting surface 34a of the supporting frame 34. An X-axis moving table 30b that has a surface along the XZ plane is slidably fitted to the pair of X-axis guide rails 30a.

An X-axis ball screw 30c is disposed between the pair of X-axis guide rails 30a along the longitudinal direction of the X-axis guide rails 30a. The X-axis ball screw 30c penetrates a nut (not illustrated) which is provided on the back side of the X-axis moving table 30b. An X-axis pulse motor 30d is coupled to one end of the X-axis ball screw 30c. The X-axis moving table 30b is moved in a direction along the X-direction by actuating the X-axis pulse motor 30d.

On an upper portion and a lower portion of the X-axis moving table 30b of the adjustment moving mechanism 30, the mirrors 22A and 22B are attached respectively. The laser beam 8 is reflected by these mirrors, so that the direction of the laser beam 8 can be changed.

Incidentally, there may be provided a mechanism for moving the irradiating unit 26 and the chuck table 16 in the vertical direction (Z-direction). However, a detailed description thereof is omitted here.

Further, the laser processing apparatus 2 includes a controller 36 that monitors and controls actions of the respective parts constituting the laser processing apparatus 2. The controller 36 is connected to the workpiece holding mechanism 6 and the irradiating mechanism 10 and inputs control signals to these mechanisms. In this way, the controller 36 operates the respective parts including the Y-axis pulse motor 14d of the moving mechanism 14, the chuck table 16, the laser oscillator 18 of the irradiating mechanism 10, the X-axis pulse motor 28d of the irradiating unit moving mechanism 28, and the X-axis pulse motor 30d of the adjustment moving mechanism 30.

The controller 36 is constituted by a computer, for example. Specifically, the controller 36 includes a computing unit that performs processing such as computation necessary to operate the respective parts and a storage unit that stores various kinds of information (data, a program, and the like). The processing unit includes a processor such as a central processing unit (CPU). In addition, the storage unit includes memories such as a read only memory (ROM) and a random access memory (RAM).

The controller 36 is connected with a display unit 36a that displays various kinds of information related to the operation of the laser processing apparatus 2 and an input unit 36b for inputting operations of the respective parts.

The display unit 36a and the input unit 36b may be a touch panel type display, for example. In this case, the display unit 36a displays, for example, an operating screen for inputting various kinds of information, commands, and the like to the laser processing apparatus 2. An operator can input information to the controller 36 by performing a touch operation on the operating screen. That is, the touch panel type display can function as both the display unit 36a and the input unit 36b. The display unit 36a and the input unit 36b may alternatively be separate pieces of equipment. In this case, for example, the display unit 36a may be a liquid crystal display, and the input unit 36b may be input equipment such as a mouse or a keyboard which is provided independently of the liquid crystal display.

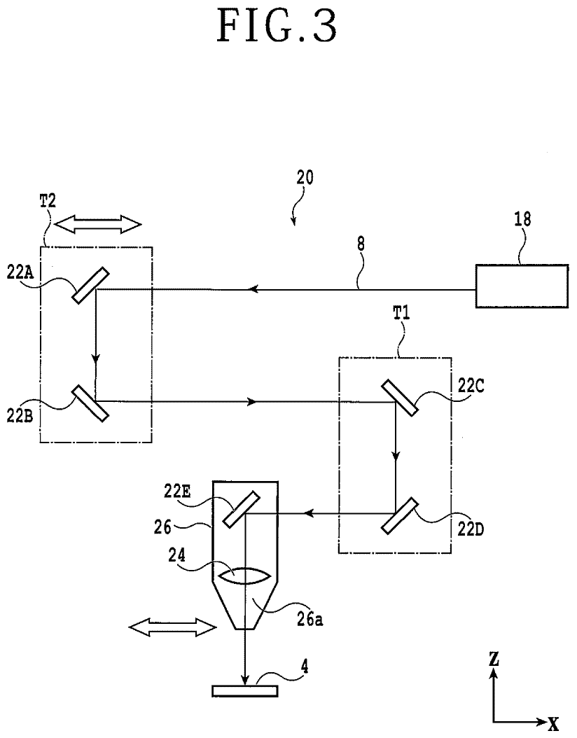

An arrangement of the optical elements in the optical system 20 will be described with reference to FIG. 3. FIG. 3 is a conceptual diagram schematically illustrating an arrangement of the optical system in the optical processing apparatus according to the first embodiment.

In the optical system 20 according to the first embodiment, the optical path of the laser beam 8 from the laser oscillator 18 as light source equipment to the workpiece 4 in the irradiation target region is set along the XZ plane. The laser beam 8 emitted from the laser oscillator 18 along the X-direction is reflected by the mirrors 22A to 22E in order and is then applied downward (along the Z-direction) from the irradiation head 26a of the irradiating unit 26 located on the most downstream side of the optical path.

That is, four of the reflection type optical elements, i.e., first to fourth optical elements, (mirrors 22A, 22B, 22C, and 22D) are provided on the upstream side of the optical path of the laser beam 8 with respect to the mirror 22E and the condensing lens 24 constituting part of the irradiating unit 26 configured as the movable optical part.

Incidentally, an attenuator or the like that adjusts a light amount of the laser beam 8 may be provided on the optical path. However, an illustration thereof is omitted here.

In the first embodiment, the mirrors 22A to 22E are each disposed so as to form an angle of 45 degrees with respect to the direction of incidence of the laser beam 8. The mirror 22A reflects downward (in a direction along the Z-direction) the laser beam 8 emitted from the laser oscillator 18 along the horizontal direction (X-direction). The mirror 22B is disposed below the mirror 22A and reflects the laser beam 8 reflected downward from the mirror 22A in a direction along the X-direction.

The direction in which the mirror 22B reflects the laser beam 8 is opposite to the direction in which the laser beam 8 is emitted from the laser oscillator 18. Thus, the mirrors 22A and 22B reverse the direction of the laser beam 8.

The mirror 22C reflects downward (in a direction along the Z-direction) the laser beam 8 reflected from the mirror 22B in the horizontal direction (X-direction). The mirror 22D is disposed below the mirror 22C and reflects the laser beam 8 reflected downward from the mirror 22C in a direction along the X-direction.

The direction in which the mirror 22D reflects the laser beam 8 is opposite to the direction in which the mirror 22B reflects the laser beam 8. Thus, the mirrors 22C and 22D reverse the direction of the laser beam 8 again.

The laser beam 8 reflected from the mirror 22D in the X-direction is reflected by the mirror 22E included in the irradiating unit 26. Then, the laser beam 8 passes through the condensing lens 24 disposed below the mirror 22E and is applied from the irradiation head 26a to the workpiece 4.

As described above, in the optical processing apparatus (laser processing apparatus) 2 and the optical system 20 according to the first embodiment, the laser beam 8 enters the first mirror 22A in the same direction (leftward direction) as the direction of incidence of the laser beam 8 on the irradiating unit 26 with respect to a movement direction of the irradiating unit 26 (X-direction). Then, the laser beam 8 is reflected by the first mirror 22A in a direction (downward direction) intersecting the movement direction of the irradiating unit 26 and enters the second mirror 22B. Subsequently, the laser beam 8 is reflected by the second mirror 22B in the opposite direction (rightward direction) to the direction of incidence of the laser beam 8 on the irradiating unit 26 with respect to the movement direction of the irradiating unit 26 (X-direction), and enters the third mirror 22C. Further, the laser beam 8 is reflected by the third mirror 22C in the direction (downward direction) intersecting the movement direction of the irradiating unit 26 and enters the fourth mirror 22D. Then, the laser beam 8 is reflected by the fourth mirror 22D and enters the irradiating unit 26 in parallel with the movement direction of the irradiating unit 26 (X-direction).

Incidentally, “the laser beam 8 enters in the same direction as/opposite direction to the direction of incidence of the laser beam 8 on the irradiating unit 26 with respect to the movement direction of the irradiating unit 26 (X-direction)” referred to herein does not mean that the direction of the laser beam 8 is exactly in parallel with the X-direction (left-right direction), but indicates that an X-component of the direction of the laser beam 8 corresponds to either side (left side or right side) of the X-direction. That is, in a case where the direction of incidence of the laser beam 8 on the irradiating unit 26 is a leftward direction along the X-direction, for example, “the same direction as the direction of incidence of the laser beam 8 on the irradiating unit 26 with respect to the movement direction of the irradiating unit 26 (X-direction)” includes not only a direction exactly coinciding with the X-direction but also a direction inclined at an angle of less than 90° in the Y-direction or the Z-direction.

When the workpiece 4 is irradiated with the laser beam 8, conditions for the irradiation are set as appropriate according to the kind of the workpiece 4 and the details of laser processing performed on the workpiece 4.

For example, in a case where the workpiece 4 which is a wafer formed of single crystal silicon is to be divided, the irradiation conditions of the laser beam 8 are set such that a region of the workpiece 4 irradiated with the laser beam 8 is modified by multiphoton absorption. Other irradiation conditions are also set such that the workpiece 4 is modified appropriately.

The irradiating unit 26 is moved in the processing feed direction (direction along the X-direction) by actuating the irradiating unit moving mechanism 28 (see FIG. 1) while the laser beam 8 is applied and condensed within the workpiece 4. The laser beam 8 applied from the irradiating unit 26 moves along the processing feed direction with respect to the workpiece 4 held on the chuck table 16. Within the workpiece 4, the material of the workpiece 4 is modified by multiphoton absorption, and thus, a modified layer is formed therein along a street.

When the application of the laser beam 8 along one street is completed, the moving mechanism 14 of the workpiece holding mechanism 6 is actuated to move the chuck table 16 in the indexing feed direction (direction along the Y-direction) by a distance corresponding to an interval between the streets. Thereafter, laser processing along the processing feed direction is performed as in the foregoing. The workpiece 4 is irradiated with the laser beam 8 along a plurality of streets by repeating a similar procedure.

Further, the chuck table 16 is rotated by 90 degrees about the axis along the Z-direction, and then, a procedure similar to that described above is repeated. A plurality of modified layers are thus formed in a lattice manner along the streets within the workpiece 4.

Regions of the workpiece 4 in which the modified layers are formed are more fragile than the other regions. Therefore, when an external force is applied to the workpiece 4, the workpiece 4 is divided along the streets with the modified layers as a starting point. That is, the modified layers function as a starting point of division of the workpiece 4.

Incidentally, there is no limitation on the details of the laser processing. For example, the workpiece 4 may be subjected to ablation processing by the laser beam 8 having a wavelength absorbed by the material of the workpiece 4. In that case, the ablation processing forms, for example, grooves extending from a top surface to an undersurface of the workpiece 4 along the streets. The workpiece 4 is thus divided.

In the step of the laser processing as described above, the irradiating unit moving mechanism 28 moves the irradiating unit 26 as the movable optical part along the X-direction, which changes a distance from the mirror 22D to the mirror 22E among the optical elements constituting the optical system 20. In the optical processing apparatus (laser processing apparatus) 2 and the optical system 20 according to the first embodiment, the adjustment moving mechanism 30 is actuated to move other optical elements (mirrors 22A and 22B) in line with the change in the distance between the mirror 22D and the mirror 22E. Accordingly, it is possible to accommodate the variation in the distance between the mirrors 22D and 22E and thus suppress a variation in the optical path length from the laser oscillator 18 to the workpiece 4.

That is, when the movable optical part (irradiating unit) 26 is moved to the left in FIG. 3, for example, the optical path from the mirror 22D to the mirror 22E is lengthened. At this time, the adjustment moving mechanism 30 (see FIG. 1) moves the mirrors 22A and 22B to the right along with the movement of the irradiating unit 26, so that the optical path from the laser oscillator 18 to the mirror 22C is shortened. A variation in the optical path length as a whole can consequently be suppressed. In this case, the adjustment moving mechanism 30 is only required to move the mirrors 22A and 22B along the X-direction by d/2 to the opposite side to the side to which the irradiating unit 26 is moved, in which “d” represents an amount of the movement of the irradiating unit 26 along the X-direction by the irradiating unit moving mechanism 28.

Conversely, when the irradiating unit 26 is moved to the right by the amount d of movement, the mirrors 22A and 22B are moved to the left by d/2.

Such an adjustment of the optical path by moving the mirrors 22A and 22B along with the movement of the irradiating unit 26 is controlled by the controller 36 according to, for example, a program stored in the storage unit of the controller 36, or the like.

When the processing on the workpiece 4 is performed by using the laser beam 8 as described above, a variation in the optical path length can lead to a variation in a state of irradiation of the workpiece 4 (an enlargement of a spot diameter, a variation in the position of a focus, or the like) in a case where the laser beam 8 is not precisely collimated light, a case where there are optical elements (condensing lens 24 and the like) that converge and diffuse the laser beam in the middle of the optical path, a case where the laser beam is branched in the middle of the optical path, which is not illustrated in the figure, and other cases.

Accordingly, the optical processing apparatus (laser processing apparatus) 2 and the optical system 20 according to the first embodiment are provided with the adjustment moving mechanism 30 for moving some of the optical elements (mirrors 22A and 22B) constituting the optical system 20, and are configured to suppress a change in the optical path length by moving the mirrors 22A and 22B along with the movement of the irradiating unit 26.

According to the technology described in Patent Document 2, for example, there has already been proposed a mechanism for adjusting the optical path length in a similar manner as described above. However, with the technology described in Patent Document 2, a movement direction of an optical element for adjusting the optical path length according to the movement of a movable optical part needs to be the same as a movement direction of the movable optical part. That is, when an objective lens as a movable optical part is moved to the right, for example, a mirror is moved to the right in order to adjust the optical path length, and when the objective lens is moved to the left, the mirror is moved to the left.

When the optical element is moved according to the movement of the movable optical part as described above, the optical element and the movable optical part are moved in the same direction. This changes a gravity center greatly. When the position of the gravity center moves greatly within the optical system or within the apparatus, a tilt or vibration may occur, and therefore, the movement of the gravity center is preferably reduced as much as possible.

In the laser processing apparatus 2 and the optical system 20 according to the first embodiment, as in the technology described in Patent Document 2, along with the movement of the irradiating unit 26 as the movable optical part at a time of laser processing, other optical elements (mirrors 22A and 22B) are moved to adjust the optical path length. However, at that time, a variation in the gravity center is suppressed by moving the irradiating unit 26 and the other optical elements in opposite directions.

Such an adjustment of the optical path length by moving the optical elements as described above is made possible by the following configuration. More specifically, the optical path of the laser beam 8 is reversed at least twice or more by the optical elements with respect to the movement direction of the irradiating unit 26 configured as the movable optical part (direction along the X-direction). That is, the optical path of the laser beam 8 has two or more reversed portions. The optical elements which form an even-numbered reversed portion of the optical path as viewed from the irradiating unit 26 are moved with respect to the movement direction of the optical part (irradiating unit) 26 (direction along the X-direction), thereby enabling the above-mentioned adjustment.

In the optical system 20 illustrated in FIG. 3, the laser beam 8 emitted from the laser oscillator 18 is reflected and changed in direction a total of five times by the mirrors 22A to 22E. With respect to the movement direction of the irradiating unit 26 (direction along the X-direction), the optical path of the laser beam 8 emitted from the laser oscillator 18 is first reversed by the mirrors 22A and 22B and is then reversed again by the mirrors 22C and 22D.

When the optical path is seen from the irradiating unit 26 as the movable optical part to the upstream side, the mirrors 22C and 22D form a first reversed portion of the optical path (indicated by a reference sign T1 in FIG. 3), and the mirrors 22A and 22B form a second reversed portion of the optical path (indicated by a reference sign T2). The mirrors 22A and 22B forming the second reversed portion are made movable along the X-direction by the adjustment moving mechanism 30. Therefore, it is possible to cancel out a variation in the optical path length which is caused by the movement of the irradiating unit 26 along the X-direction, by moving the optical elements (mirrors 22A and 22B) in the opposite direction to the movement of the irradiating unit 26 with respect to the X-direction.

If the mirrors 22C and 22D forming the first reversed portion T1 as viewed from the irradiating unit 26 are provided with a similar adjustment moving mechanism to cancel out a variation in the optical path length which is caused by the movement of the irradiating unit 26, the mirrors 22C and 22D need to be moved in the same direction as the movement of the irradiating unit 26 with respect to the X-direction. The movements of the irradiating unit 26 and the mirrors 22C and 22D change the gravity center greatly.

For this reason, when a variation in the gravity center is to be suppressed, an adjustment of the optical path length by the adjustment moving mechanism needs to be performed on the optical elements forming the even-numbered reversed portion of the optical path, instead of the optical elements forming an odd-numbered reversed portion of the optical path as viewed from the movable optical part.

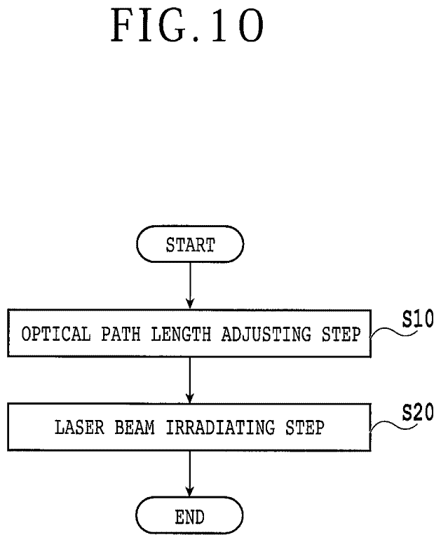

The above procedure is summarized as in FIG. 10. FIG. 10 is a flowchart of assistance in explaining the procedure of a laser processing method using the optical system 20 described above. The procedure illustrated in this flowchart includes an optical path length adjusting step (step S10) and a laser beam irradiating step (step S20). The optical path length adjusting step (step S10) is a step of adjusting the optical path length of the laser beam 8 by, along with the movement of the movable optical part (irradiating unit) 26, moving the optical elements (mirrors 22A and 22B) by the adjustment moving mechanism 30 in the opposite direction to the movement direction of the movable optical part (irradiating unit) 26. The laser beam irradiating step (step S20) is a step of irradiating the workpiece 4 with the laser beam 8. Incidentally, while FIG. 10 illustrates the laser beam irradiating step (step S20) following the optical path length adjusting step (step S10), these steps may be performed alternately or performed simultaneously and in parallel with each other.

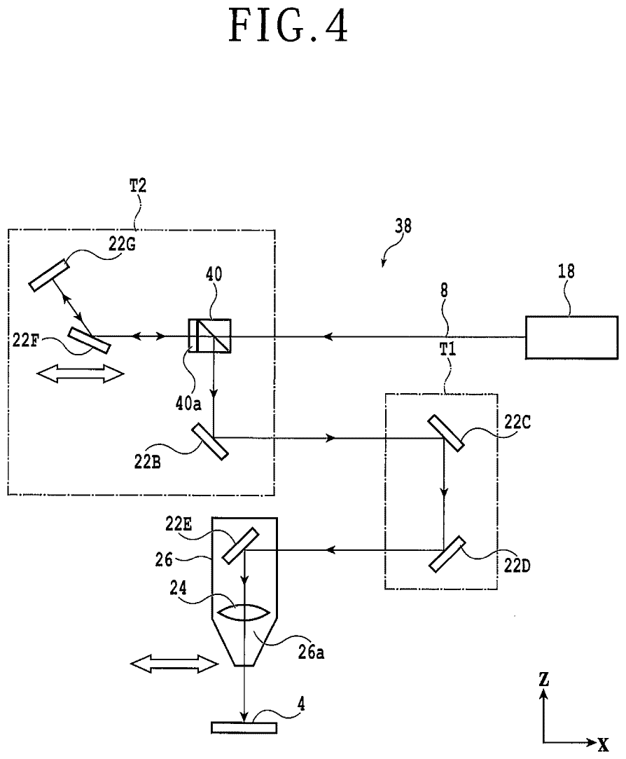

FIG. 4 is a conceptual diagram schematically illustrating another example (second embodiment) of the arrangement of the optical system in the optical processing apparatus. A basic configuration is similar to that of the first embodiment illustrated in FIG. 3. However, the difference lies in that a polarization beam splitter 40 is provided as an optical element in the middle of the optical path.

A mechanism constituted by the polarization beam splitter 40 and mirrors 22F and 22G disposed in the vicinity of the polarization beam splitter 40 is equivalent to a mechanism constituted by a polarization beam splitter and first and second mirrors illustrated in FIG. 1 of Patent Document 2.

In an optical system 38 according to the second embodiment included in FIG. 4 of the present application, the polarization beam splitter 40 is disposed on an optical path between the laser oscillator 18 and the mirror 22F. A portion of the polarization beam splitter 40 facing the mirror 22F side is provided with a wave plate 40a that converts a polarization state of the laser beam 8.

The wave plate 40a, for example, converts the laser beam 8 applied as linearly polarized light from the laser oscillator 18 into circularly polarized light. The laser beam 8 that has become the circularly polarized light is reflected by the mirrors 22F and 22G, and returns to the polarization beam splitter 40. A component of the laser beam 8 returned to the polarization beam splitter 40 which component is reversed in a rotational direction is converted into linearly polarized light with a polarization direction thereof rotated by 90 degrees from that at a time of the emission from the laser oscillator 18.

With such a mechanism, the laser beam 8 from the laser oscillator 18 is transmitted as it is through the polarization beam splitter 40, whereas the laser beam 8 entering the polarization beam splitter 40 from the mirrors 22F and 22G through the wave plate 40a is reflected downward.

The laser beam 8 reflected downward from the polarization beam splitter 40 is reflected in a direction along the X-direction by the mirror 22B provided below the polarization beam splitter 40. A configuration of the optical system 38 from the mirrors 22B to 22E, the condensing lens 24, and the irradiating unit 26 is equivalent to that of the first embodiment described with reference to FIG. 3.

In this way, in the optical system 38 according to the second embodiment illustrated in FIG. 4, the first reversed portion T1 of the optical path of the laser beam 8 as viewed from the irradiating unit 26 as the movable optical part is formed by the mirrors 22C and 22D, and the second reversed portion T2 is formed by the mirrors 22B, 22F, and 22G and the polarization beam splitter 40.

The mirrors 22F and 22G forming the second reversed portion T2 are provided with a mechanism similar to the adjustment moving mechanism 30 (see FIG. 1) described above in such an optical system 38, and these mirrors are configured to be movable in the X-direction. This makes it possible to adjust the optical path length while suppressing a variation in the gravity center, by moving the mirrors in a similar manner to the foregoing first embodiment.

Incidentally, in adjusting the optical path length by the movement of the optical elements in the second embodiment, the polarization beam splitter 40 and the mirror 22B may also be moved in addition to the mirrors 22F and 22G.

Alternatively, the optical path length can also be adjusted in a similar manner by moving the mirror 22G along a direction connecting the upper left side and the lower right side of FIG. 4 to each other. In that case, the movement direction of the mirror 22G as an optical element forming the reversed portion T2 of the optical path is greatly inclined with respect to the X-direction. However, the movement direction also includes a component in the X-direction. It is therefore possible to suppress a variation in the gravity center which is caused by the movement of the irradiating unit 26 along the X-direction and the adjustment of the optical path length.

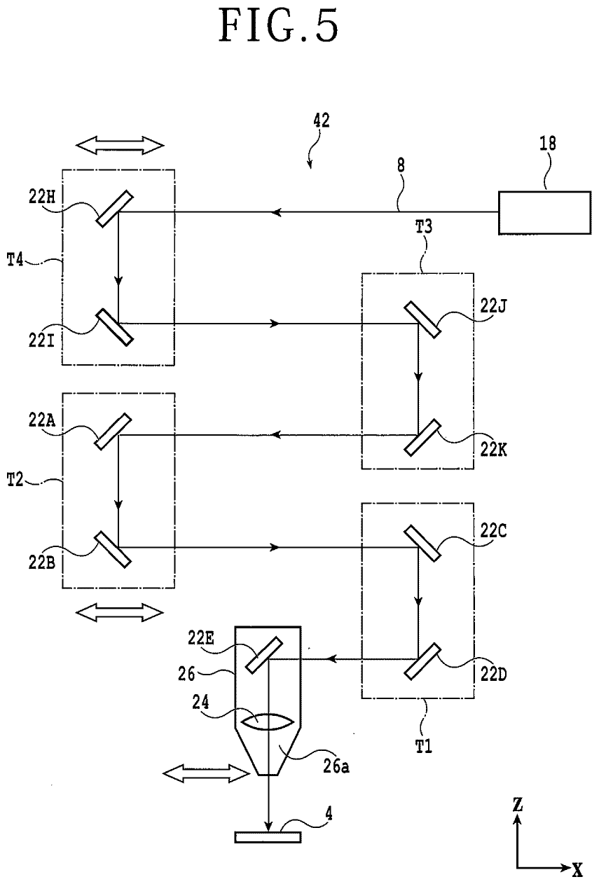

FIG. 5 is a conceptual diagram schematically illustrating yet another example (third embodiment) of the arrangement of the optical system in the optical processing apparatus. In the first embodiment illustrated in FIG. 3, the mirrors 22A to 22D as optical elements form the reversed portions T1 and T2 at two positions on the optical path of the laser beam 8 with respect to the X-direction. In the third embodiment illustrated in FIG. 5, four mirrors 22H to 22K are further provided to an optical system 42, and reversed portions T1 to T4 are thus formed at four positions on the optical path.

The four mirrors 22H to 22K are located on the upstream side of the mirrors 22A to 22E (between the laser oscillator 18 and the mirror 22A on the optical path). An arrangement of the mirrors 22A to 22E is substantially similar to the arrangement of the mirrors 22A to 22E in the first embodiment illustrated in FIG. 3. An arrangement of the mirrors 22H to 22K on the upstream side corresponds to the arrangement of the mirrors 22A to 22D.

In the optical system 42 according to the third embodiment, the laser beam 8 emitted to the left along the X-direction from the laser oscillator 18 located on the upper right side of FIG. 5 is first reflected downward by the mirror 22H, reflected rightward by the mirror 22I, reflected downward by the mirror 22J, and then reflected leftward by the mirror 22K.

The laser beam 8 reflected leftward from the mirror 22K enters the mirror 22A. Subsequently, the laser beam 8 is reflected downward by the mirror 22A, reflected rightward by the mirror 22B, reflected downward by the mirror 22C, reflected leftward by the mirror 22D, and then reflected by the mirror 22E included in the irradiating unit 26. The laser beam 8 passes through the condensing lens 24 and is applied from the irradiation head 26a to the workpiece 4 placed below the irradiation head 26a.

In such an optical system 42, as viewed from the irradiating unit 26 as a movable optical part, the first reversed portion T1 of the optical path with respect to the X-direction is formed by the mirrors 22C and 22D, the second reversed portion T2 is formed by the mirrors 22A and 22B, a third reversed portion T3 is formed by the mirrors 22J and 22K, and a fourth reversed portion T4 is formed by the mirrors 22H and 22I.

Moreover, the mirrors 22A and 22B and the mirrors 22H and 22I forming the even-numbered reversed portions, i.e., the second reversed portion T2 and the fourth reversed portion T4, among the reversed portions of the optical path are movable along the X-direction by a mechanism similar to the adjustment moving mechanism 30 (see FIG. 1) described above.

Such a mechanism can also adjust the optical path length according to the movement of the irradiating unit 26 along the X-direction by moving the mirrors in a similar manner to the foregoing first and second embodiments, while suppressing a variation in the gravity center. It is to be noted that, in the third embodiment, when the mirrors 22A and 22B and the mirrors 22H and 22I forming the reversed portions T2 and T4 are moved at the same time, they are moved along the X-direction by d/4 to the opposite side to the side to which the irradiating unit 26 is moved, in which “d” represents an amount of the movement of the irradiating unit 26 along the X-direction.

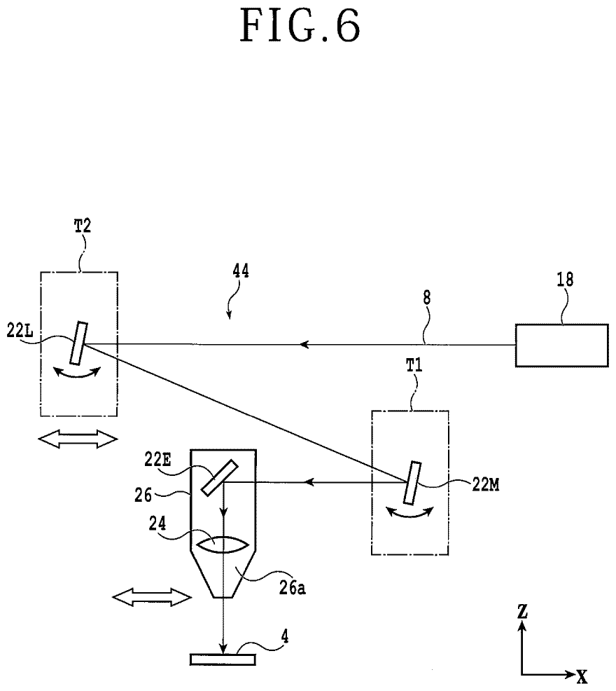

FIG. 6 is a conceptual diagram schematically illustrating yet another example (fourth embodiment) of the arrangement of the optical system in the optical processing apparatus. In the foregoing first and third embodiments illustrated in FIG. 3 and FIG. 5, the mirrors 22A to 22D and the mirrors 22H to 22K are each disposed at an angle of 45 degrees with respect to the direction of the laser beam 8 to change the direction of the laser beam 8 by 90 degrees by each of the mirrors, thereby forming the reversed portions T1 to T4. That is, two mirrors are arranged to form each reversed portion in the first and third embodiments. In an optical system 44 according to the fourth embodiment, however, one mirror 22L forms the reversed portion T2, and one mirror 22M forms the reversed portion T1.

In such a case, the direction of the laser beam 8 entering the reversed portion T1 or T2 and the direction of the laser beam 8 traveling therefrom are not parallel with each other. However, it is possible to adjust the optical path length while suppressing a variation in the gravity center, by moving the position of the mirror 22L along the X-direction along with the movement of the irradiating unit 26 as the movable optical part along the X-direction and, at the same time, adjusting the angles of the mirrors 22L and 22M, for example. Incidentally, in this case, an appropriate amount of the movement of the mirror 22L with respect to an amount of the movement of the irradiating unit 26 along the X-direction and appropriate angles of the mirrors 22L and 22M differ according to the positional relation between the mirrors 22L and 22M.

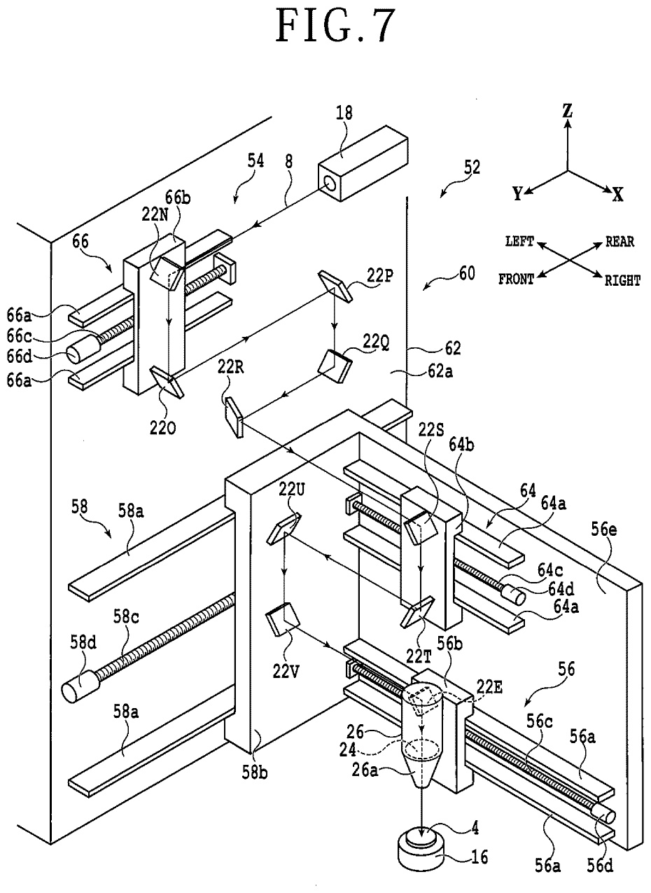

FIG. 7 is a perspective view illustrating yet another example (fifth embodiment) of the form of the optical processing apparatus. In the foregoing first to fourth embodiments, the irradiating unit 26 as the movable optical part is assumed to be moved only a direction along the X-direction. However, in an optical processing apparatus (laser processing apparatus) 52 and an optical system 54 according to the fifth embodiment, the irradiating unit 26 is assumed to be moved in two directions, that is, the X-direction and the Y-direction, with respect to the horizontal direction, and such a mechanism is provided which adjusts the optical path length according to the movement of the irradiating unit 26 along each direction while suppressing a variation in the gravity center.

A laser processing apparatus 52 according to the fifth embodiment is provided with an X-axis moving mechanism 56 and a Y-axis moving mechanism 58 as an irradiating unit moving mechanism that moves the irradiating unit 26 along the horizontal direction with respect to the chuck table 16 holding the workpiece 4.

The X-axis moving mechanism 56 and the Y-axis moving mechanism 58 have, for example, a mechanism similar to the irradiating unit moving mechanism 28 in the foregoing first embodiment (see FIG. 1).

The X-axis moving mechanism 56 and the Y-axis moving mechanism 58 are supported by a supporting frame 62 that, as a whole, constitutes a supporting mechanism 60. The supporting frame 62 has a supporting surface 62a along a YZ plane. The Y-axis moving mechanism 58 is attached to the supporting surface 62a, and the X-axis moving mechanism 56 is further attached to the Y-axis moving mechanism 58.

The Y-axis moving mechanism 58 includes a pair of Y-axis guide rails 58a that extend in parallel with each other along the Y-direction on the supporting surface 62a of the supporting frame 62. A Y-axis moving table 58b that has a surface along the YZ plane is slidably fitted to the pair of Y-axis guide rails 58a.

A Y-axis ball screw 58c is disposed along the longitudinal direction of the Y-axis guide rails 58a between the pair of Y-axis guide rails 58a. The Y-axis ball screw 58c penetrates a nut (not illustrated) which is provided on the back side (facing the supporting surface 62a of the supporting frame 62) of the Y-axis moving table 58b. A Y-axis pulse motor 58d is coupled to one end of the Y-axis ball screw 58c. The Y-axis moving table 58b is moved in a direction along the Y-direction by actuating the Y-axis pulse motor 58d.

The X-axis moving mechanism 56 is attached to the Y-axis moving table 58b of the Y-axis moving mechanism 58. The X-axis moving mechanism 56 includes a pair of X-axis guide rails 56a, an X-axis moving table 56b, an X-axis ball screw 56c, and an X-axis pulse motor 56d as well as a base portion 56e that supports these.

The base portion 56e is a member that is attached to the surface of the Y-axis moving table 58b and extends along the XZ plane. The pair of X-axis guide rails 56a that extend in parallel with each other along the X-direction is provided to a surface of the base portion 56e on the near side in the Y-direction. The X-axis moving table 56b that has a surface along the XZ plane is slidably fitted to the pair of X-axis guide rails 56a.

The X-axis ball screw 56c is disposed between the pair of X-axis guide rails 56a along the longitudinal direction of the X-axis guide rails 56a. The X-axis ball screw 56c penetrates a nut (not illustrated) which is provided on the back side (facing the base portion 56e) of the X-axis moving table 56b. The X-axis pulse motor 56d is coupled to one end of the X-axis ball screw 56c.

The X-axis moving table 56b is moved in a direction along the X-direction by actuating the X-axis pulse motor 56d. The irradiating unit 26 including the mirror 22E and the condensing lens 24 is attached to the X-axis moving table 56b.

As described above, the irradiating unit 26 as the movable optical part is configured to be movable in the X-axis direction by the X-axis moving mechanism 56 as the irradiating unit moving mechanism and movable in the Y-axis direction together with the X-axis moving mechanism 56 by the Y-axis moving mechanism 58 as the irradiating unit moving mechanism.

In addition to this, according to the fifth embodiment, mirrors 22N to 22V as optical elements constituting the optical system 54 are further provided.

The laser beam 8 is emitted to the near side (to the front) of FIG. 7 along the Y-direction from the laser oscillator 18 disposed on the upper right rear side of FIG. 7 and is reflected downward by the mirror 22N disposed forward of the laser oscillator 18. The laser beam 8 reflected downward by the mirror 22N is reflected to the rear side (rearward) of FIG. 7 by the mirror 22O disposed below the mirror 22N.

The laser beam 8 reflected rearward by the mirror 22O is reflected downward by the mirror 22P disposed rearward of the mirror 22O. The laser beam 8 reflected downward by the mirror 22P is reflected forward by the mirror 22O disposed below the mirror 22P and is then reflected rightward along the X-direction by the mirror 22R disposed forward of the mirror 22Q.

The laser beam 8 reflected rightward by the mirror 22R is reflected downward by the mirror 22S disposed rightward of the mirror 22R. The laser beam 8 reflected downward by the mirror 22S is reflected leftward by the mirror 22T disposed below the mirror 22S.

The laser beam 8 reflected leftward by the mirror 22T is reflected downward by the mirror 22U disposed leftward of the mirror 22T. The laser beam 8 reflected downward by the mirror 22U is reflected rightward by the mirror 22V disposed below the mirror 22U.

The irradiating unit 26 is located rightward of the mirror 22V. The laser beam 8 reflected rightward by the mirror 22V enters the mirror 22E within the irradiating unit 26 and is reflected downward by the mirror 22E. Then, the laser beam 8 passes through the condensing lens 24 and is applied from the irradiation head 26a to the workpiece 4 placed below the irradiation head 26a.

Of these mirrors 22N to 22V constituting the optical system 54, the mirrors 22N to 22R, together with the laser oscillator 18, are disposed along the supporting surface 62a of the supporting frame 62 that lies along the YZ plane. Further, the mirrors 22N and 22O among the mirrors 22N to 22R are disposed so as to be movable along the Y-axis with respect to the supporting surface 62a by a Y-axis moving mechanism 66 as an adjustment moving mechanism.

The mirrors 22S to 22V are disposed along the base portion 56e of the X-axis moving mechanism 56 that lies along the XZ plane. Further, the mirrors 22S and 22T among the mirrors 22S to 22V are disposed so as to be movable along the base portion 56e by an X-axis moving mechanism 64 as the adjustment moving mechanism.

The X-axis moving mechanism 64 and the Y-axis moving mechanism 66 as the adjustment moving mechanism can be configured as mechanisms substantially similar to the X-axis moving mechanism 56 and the Y-axis moving mechanism 58 as the irradiating unit moving mechanism as described below, for example.

The X-axis moving mechanism 64 includes a pair of X-axis guide rails 64a that extend in parallel with each other along the X-direction on the surface of the base portion 56e. An X-axis moving table 64b that has a surface along the XZ plane is slidably fitted to the pair of X-axis guide rails 64a.

An X-axis ball screw 64c is disposed between the pair of X-axis guide rails 64a along the longitudinal direction of the X-axis guide rails 64a. The X-axis ball screw 64c penetrates a nut (not illustrated) which is provided on the back side (facing the base portion 56e) of the X-axis moving table 64b. An X-axis pulse motor 64d is coupled to one end of the X-axis ball screw 64c. The X-axis moving table 64b is moved in a direction along the X-direction by actuating the X-axis pulse motor 64d.

The mirrors 22S and 22T are attached to an upper portion and a lower portion of the X-axis moving table 64b included in the X-axis moving mechanism 64 as the adjustment moving mechanism. The mirrors 22U and 22V are attached to the Y-axis moving table 58b included in the Y-axis moving mechanism 58 as the irradiating unit moving mechanism.

The Y-axis moving mechanism 66 includes a pair of Y-axis guide rails 66a that extend in parallel with each other along the Y-direction on the supporting surface 62a of the supporting frame 62. A Y-axis moving table 66b that has a surface along the YZ plane is slidably fitted to the pair of Y-axis guide rails 66a.

A Y-axis ball screw 66c is disposed between the pair of Y-axis guide rails 66a along the longitudinal direction of the Y-axis guide rails 66a. The Y-axis ball screw 66c penetrates a nut (not illustrated) which is provided on the back side (facing the supporting surface 62a) of the Y-axis moving table 66b. A Y-axis pulse motor 66d is coupled to one end of the Y-axis ball screw 66c. The Y-axis moving table 66b is moved in a direction along the Y-direction by actuating the Y-axis pulse motor 66d.

The mirrors 22N and 22O are attached to an upper portion and a lower portion of the Y-axis moving table 66b included in the Y-axis moving mechanism 66 as the adjustment moving mechanism. The mirrors 22P, 22Q, and 22R are attached to the supporting surface 62a of the supporting frame 62.

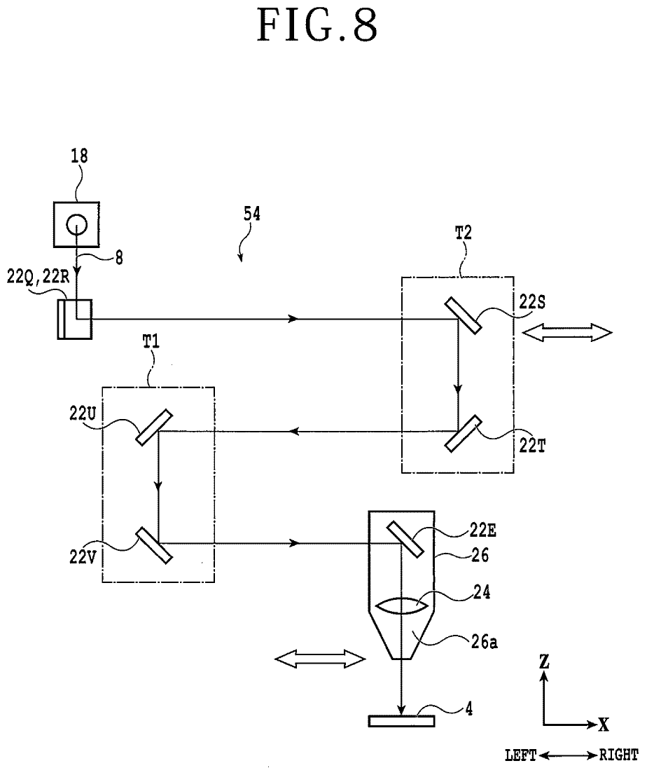

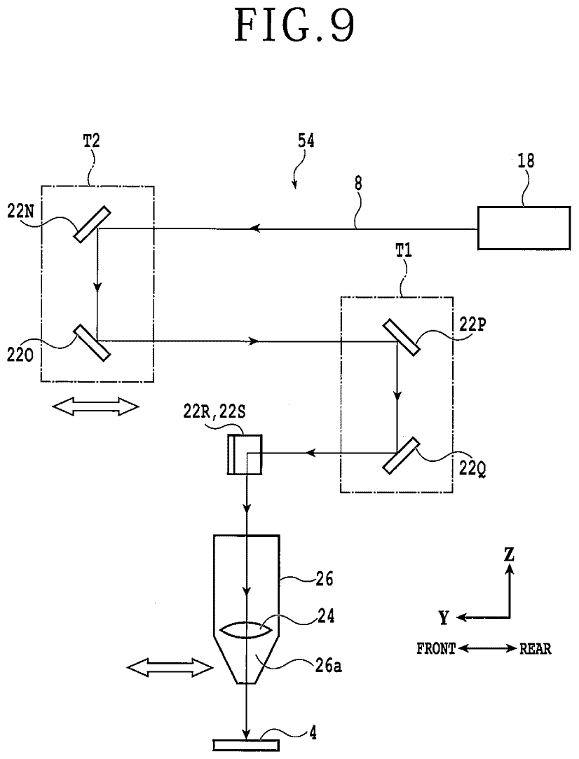

FIG. 8 and FIG. 9 are conceptual diagrams schematically illustrating an arrangement of the optical system 54 in the optical processing apparatus according to the fifth embodiment illustrated in FIG. 7, and illustrate the arrangement as viewed from the Y-direction and the X-direction, respectively.

As illustrated in FIG. 8, with respect to the X-direction (left-right direction), reversed portions T1 and T2 are formed at two positions on the optical path of the laser beam 8 between the irradiating unit 26 as the movable optical part and the laser oscillator 18 located on the most upstream side of the optical path as viewed from the irradiating unit 26. Of these, the first reversed portion T1 is formed by the mirrors 22U and 22V. The second reversed portion T2 is formed by the mirrors 22S and 22T.

Moreover, the mirrors 22S and 22T forming the even-numbered reversed portion T2 are configured to be movable along the X-direction by the X-axis moving mechanism 64 (see FIG. 7) as the adjustment moving mechanism. It is thus possible to adjust the optical path length according to the movement of the irradiating unit 26 along the X-direction while suppressing a variation in the gravity center.

Meanwhile, as illustrated in FIG. 9, with respect to the Y-direction (front-rear direction), reversed portions T1 and T2 are also formed at two positions on the optical path of the laser beam 8 between the irradiating unit 26 as the movable optical part and the laser oscillator 18 located on the most upstream side of the optical path as viewed from the irradiating unit 26. Of these, the first reversed portion T1 is formed by the mirrors 22P and 22O. The second reversed portion T2 is formed by the mirrors 22N and 22O.

Moreover, the mirrors 22N and 22O forming the even-numbered reversed portion T2 are configured to be movable along the Y-direction by the Y-axis moving mechanism 66 (see FIG. 7) as the adjustment moving mechanism. It is thus possible to adjust the optical path length according to the movement of the irradiating unit 26 along the Y-direction while suppressing a variation in the gravity center.

Besides, each of the foregoing embodiments can be modified as appropriate without departing from the objective scope of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. An optical processing apparatus for irradiating a workpiece with a laser beam, the optical processing apparatus comprising:
a laser oscillator configured to emit the laser beam;
an irradiating unit configured to irradiate the workpiece with the laser beam emitted from the laser oscillator;
an irradiating unit moving mechanism configured to move the irradiating unit;
a plurality of optical elements arranged on an optical path of the laser beam emitted from the laser oscillator to guide the laser beam from the laser oscillator to the irradiating unit; and
an adjustment moving mechanism configured to move the optical element with respect to a movement direction of the irradiating unit, wherein,
along with a movement of the irradiating unit, the adjustment moving mechanism moves the optical element in an opposite direction to the movement direction of the irradiating unit, thereby adjusting an optical path length of the laser beam.

2. The optical processing apparatus according to claim 1, wherein
the plurality of optical elements are arranged on the optical path of the laser beam such that reversed portions are formed at two positions or more on the optical path of the laser beam with respect to the movement direction of the irradiating unit, and
among the optical elements, the optical element forming an even-numbered reversed portion of the optical path of the laser beam as viewed from the irradiating unit is movable by the adjustment moving mechanism.

3. An optical system for guiding light to an irradiation target region by a plurality of optical elements on an optical path, the optical system comprising:
a movable optical part on the optical path configured to change the optical path by being moved; and
an adjustment moving mechanism configured to move the optical element with respect to a movement direction of the movable optical part, wherein,
along with a movement of the movable optical part, the adjustment moving mechanism moves the optical element in an opposite direction to the movement direction of the movable optical part, thereby adjusting an optical path length of a laser beam.

4. The optical system according to claim 3, wherein
the plurality of optical elements are arranged such that reversed portions are formed at two positions or more on the optical path with respect to the movement direction of the movable optical part, and
among the optical elements, the optical element forming an even-numbered reversed portion of the optical path as viewed from the movable optical part is movable by the adjustment moving mechanism.

5. The optical system according to claim 3, wherein
a direction of incidence of the light on the movable optical part along the optical path is parallel with the movement direction of the movable optical part,
as the plurality of optical elements, at least first to fourth reflection type optical elements are provided on an upstream side of the movable optical part,
the light enters the first reflection type optical element in a same direction as the direction of incidence of the light on the movable optical part with respect to the movement direction of the movable optical part,
the light is reflected by the first reflection type optical element in a direction intersecting the movement direction of the movable optical part and enters the second reflection type optical element,
the light is reflected by the second reflection type optical element in an opposite direction to the direction of incidence of the light on the movable optical part and enters the third reflection type optical element with respect to the movement direction of the movable optical part, and
the light is reflected by the third reflection type optical element in the direction intersecting the movement direction of the movable optical part and enters the fourth reflection type optical element.

6. The optical system according to claim 4, wherein
a direction of incidence of the light on the movable optical part along the optical path is parallel with the movement direction of the movable optical part,
as the plurality of optical elements, at least first to fourth reflection type optical elements are provided on an upstream side of the movable optical part,
the light enters the first reflection type optical element in a same direction as the direction of incidence of the light on the movable optical part with respect to the movement direction of the movable optical part,
the light is reflected by the first reflection type optical element in a direction intersecting the movement direction of the movable optical part and enters the second reflection type optical element,
the light is reflected by the second reflection type optical element in an opposite direction to the direction of incidence of the light on the movable optical part and enters the third reflection type optical element with respect to the movement direction of the movable optical part, and
the light is reflected by the third reflection type optical element in the direction intersecting the movement direction of the movable optical part and enters the fourth reflection type optical element.

7. A laser processing method using an optical system for guiding light to an irradiation target region by a plurality of optical elements on an optical path,
the optical system including
a movable optical part on the optical path configured to change the optical path by being moved, and
an adjustment moving mechanism configured to move the optical element with respect to a movement direction of the movable optical part,
the laser processing method comprising:
adjusting an optical path length of a laser beam by, along with a movement of the movable optical part, moving the optical element by the adjustment moving mechanism in an opposite direction to the movement direction of the movable optical part; and
irradiating a workpiece with the laser beam.
